(19) United States
(12) Patent Application Publication
(10) Pub. No.: US 2026/0136571 A1
(43) Pub. Date: May 14, 2026

(54) STACKED FET P-N DIODE

(71) Applicant: INTERNATIONAL BUSINESS MACHINES CORPORATION, Armonk, NY (US)

(72) Inventors: Debarghya Sarkar, Latham, NY (US); Ching-Tzu Chen, Ossining, NY (US); Utkarsh Bajpai, Suffern, NY (US); Henry K. Utomo, Ridgefield, CT (US)

(21) Appl. No.: 18/946,099

(22) Filed: Nov. 13, 2024

(51) Int. Cl. H01L 29/861; H01L 29/06; H01L 29/423; H01L 29/66; H01L 29/775; H01L 29/786

(52) U.S. Cl. CPC H10D 8/411; H10D 30/43; H10D 30/6713; H10D 30/6735; H10D 30/6757; H10D 62/121; H10D 30/014

(57) ABSTRACT

A semiconductor device includes gate structures having source/drain canyons disposed therebetween and a P-N junction integrated within the source/drain canyons. The P-N junction includes a first epitaxial region of a first carrier type and a second epitaxial region of a second carrier type different from the first carrier type. The second epitaxial region is vertically stacked on and in contact with the first epitaxial region.

### BACKGROUND

The present invention generally relates to semiconductor devices and processing methods, and more particularly to stacked field effect transistor (FET) devices having a P-N diode integrated into a source/drain canyon.

Semiconductor material grown from the nanosheet sides to form source and drain structures is polycrystalline with no well-defined and well-controlled termination surfaces. Using the polycrystalline semiconductor structures does not provide adequate crystalline morphology to produce a sharp P-N junction needed for reliable diode operation. At a scaled gate pitch, a source/drain (S/D) canyon is too narrow to form an effective laterally oriented P-N junction. Thus, there is no clear fabrication pathway and viable structure currently existing for a P-N diode that is readily compatible with the structure and fabrication of vertically stacked FET devices.

### SUMMARY

In accordance with an embodiment of the present invention, a semiconductor device includes gate structures having source/drain canyons disposed therebetween and a P-N junction integrated within the source/drain canyons. The P-N junction includes a first epitaxial region of a first carrier type and a second epitaxial region of a second carrier type different from the first carrier type. The second epitaxial region is vertically stacked on and in contact with the first epitaxial region.

In accordance with another embodiment of the present invention, a semiconductor device, includes gate structures having source/drain canyons disposed therebetween and a P-N junction integrated within the source/drain canyons. The P-N junction forms a diode and includes a first epitaxial region of a first carrier type and a second epitaxial region of a second carrier type different from the first carrier type. The second epitaxial region is vertically stacked on and in contact with the first epitaxial region. A first contact is electrically coupled to the first epitaxial region, and a second contact is electrically coupled to the second epitaxial region.

In accordance with another embodiment of the present invention, a semiconductor device includes gate structures having source/drain canyons disposed therebetween. A passive device region includes a P-N junction integrated within the source/drain canyons. The P-N junction forms a diode and includes a first epitaxial region of a first carrier type and a second epitaxial region of a second carrier type different from the first carrier type. The second epitaxial region is vertically stacked on and in contact with the first epitaxial region. The second epitaxial region covers three sides of the first epitaxial region. A first contact is electrically coupled to the first epitaxial region, and a second contact electrically is coupled to the second epitaxial region. An active device region includes stacked field effect transistors.

These and other features and advantages will become apparent from the following detailed description of illustrative embodiments thereof, which is to be read in connection with the accompanying drawings.

### BRIEF DESCRIPTION OF THE DRAWINGS

The following description will provide details of preferred embodiments with reference to the following figures, wherein:

FIG. 1 shows a layout view depicting section lines X1 and X2 for cross-sectional views X1 and X2 throughout the FIGS., in accordance with an embodiment of the present invention;

FIG. 2 shows cross-sectional views X1, X2 and X1 (main device region) taken at section lines X1 and X2 and depicting patterned nanosheets for forming a P-N junction and field effect transistors in a same process using similar structures, in accordance with an embodiment of the present invention;

FIG. 3 shows cross-sectional views X1, X2 and X1 (main device region) taken at section lines X1 and X2 and depicting source/drain (S/D) canyons filled between gate structures and a blocking mask applied to the main device region, in accordance with an embodiment of the present invention;

FIG. 4 shows cross-sectional views X1, X2 and X1 (main device region) taken at section lines X1 and X2 and depicting a dielectric fill in the S/D canyons partially recessed in a passive P-N junction device region, in accordance with an embodiment of the present invention;

FIG. 5 shows cross-sectional views X1, X2 and X1 (main device region) taken at section lines X1 and X2 and depicting the dielectric fill in the S/D canyons partially recessed in a main device region and fully removed in the passive P-N junction device region, in accordance with an embodiment of the present invention;

FIG. 6 shows cross-sectional views X1, X2 and X1 (main device region) taken at section lines X1 and X2 and depicting blocking spacers formed in the S/D canyons, in accordance with an embodiment of the present invention;

FIG. 7 shows cross-sectional views X1, X2 and X1 (main device region) taken at section lines X1 and X2 and depicting blocking spacers recessed from horizontal surfaces, in accordance with an embodiment of the present invention;

FIG. 8 shows cross-sectional views X1, X2 and X1 (main device region) taken at section lines X1 and X2 and depicting the dielectric fill removed from the main device area, in accordance with an embodiment of the present invention;

FIG. 9 shows cross-sectional views X1, X2 and X1 (main device region) taken at section lines X1 and X2 and depicting bottom epitaxial regions formed, in accordance with an embodiment of the present invention;

FIG. 10 shows cross-sectional views X1, X2 and X1 (main device region) taken at section lines X1 and X2 and depicting an organic polymer fill of the S/D canyons, in accordance with an embodiment of the present invention;

FIG. 11 shows cross-sectional views X1, X2 and X1 (main device region) taken at section lines X1 and X2 and depicting the organic polymer fill removed from the passive device region, in accordance with an embodiment of the present invention;

FIG. 12 shows cross-sectional views X1, X2 and X1 (main device region) taken at section lines X1 and X2 and depicting another dielectric fill in the passive device region, in accordance with an embodiment of the present invention;

FIG. 13 shows cross-sectional views X1, X2 and X1 (main device region) taken at section lines X1 and X2 and depicting the dielectric fill removed from the main device region, in accordance with an embodiment of the present invention;

FIG. 14 shows cross-sectional views X1, X2 and X1 (main device region) taken at section lines X1 and X2 and depicting a liner formed, in accordance with an embodiment of the present invention;

FIG. 15 shows cross-sectional views X1, X2 and X1 (main device region) taken at section lines X1 and X2 and depicting a fill over the liner in the main device region, in accordance with an embodiment of the present invention;

FIG. 16 shows cross-sectional views X1, X2 and X1 (main device region) taken at section lines X1 and X2 and depicting the fill recessed to a middle dielectric isolation in the main device region, in accordance with an embodiment of the present invention;

FIG. 17 shows cross-sectional views X1, X2 and X1 (main device region) taken at section lines X1 and X2 and depicting the liner removed, in accordance with an embodiment of the present invention;

FIG. 18 shows cross-sectional views X1, X2 and X1 (main device region) taken at section lines X1 and X2 and depicting the fill in the S/D canyons removed in the main device region, in accordance with an embodiment of the present invention;

FIG. 19 shows cross-sectional views X1, X2 and X1 (main device region) taken at section lines X1 and X2 and depicting top epitaxial regions formed, in accordance with an embodiment of the present invention;

FIG. 20 shows cross-sectional views X1, X2 and X1 (main device region) taken at section lines X1 and X2 and depicting another dielectric fill, in accordance with an embodiment of the present invention;

FIG. 21 shows cross-sectional views X1 and X2 taken at section lines X1 and X2 and depicting replacement metal gate structures formed, in accordance with an embodiment of the present invention;

FIG. 22 shows cross-sectional views X1 and X2 taken at section lines X1 and X2 and depicting a contact hole formed, in accordance with an embodiment of the present invention;

FIG. 23 shows cross-sectional views X1 and X2 taken at section lines X1 and X2 and depicting a contact plug formed in the contact hole, in accordance with an embodiment of the present invention;

FIG. 24 shows cross-sectional views X1 and X2 taken at section lines X1 and X2 and depicting another contact hole formed, in accordance with an embodiment of the present invention;

FIG. 25 shows cross-sectional views X1 and X2 taken at section lines X1 and X2 and depicting a liner formed in the open contact hole, in accordance with an embodiment of the present invention;

FIG. 26 shows cross-sectional views X1, X2 and Y taken at section lines X1, X2 and Y in an inset and depicting contacts being formed to complete a P-N junction device, in accordance with an embodiment of the present invention; and

FIG. 27 shows a cross-sectional view Y taken at section line Y and depicting a backside contact to complete the P-N junction device, in accordance with an embodiment of the present invention.

### DETAILED DESCRIPTION

In accordance with embodiments of the present invention, devices and methods are described which include integrating a P-N diode within a stacked field effect transistor (FET) device. The devices and methods include employing pristine crystalline material for the formation of the P-N junction of the diode. By blocking the sides of nanosheets using dielectric liners, single crystal epitaxial growth of semiconductor structure can be obtained in a source/drain (S/D) canyon using a single crystal substrate as a starting growth surface. Subsequent growth of semiconductor materials of different polarities (e.g., doping types or carrier types) gives atomically pristine interfaces to provide excellent electrical junctions. By using dielectric liners in a contact trench passing through a top semiconductor structure, and/or by employing a backside contact, a bottom semiconductor structure can be contacted.

In an embodiment, a semiconductor device includes a bottom semiconductor material region directly beneath and directly contacting a top semiconductor material region. Both the bottom semiconductor material and the top semiconductor material are arranged in a diode structure in a S/D canyon of a stacked FET architecture. S/D canyons are formed in between gate structures. Both the bottom semiconductor material and the top semiconductor material can have an opposite polarity.

In an embodiment, a semiconductor device includes semiconductor material regions of opposite polarity (e.g., majority charge carrier types) in immediate conjunction within the S/D canyon of a stacked FET structure. The semiconductor material regions can include a stack of two or more different polarity materials within the S/D canyon. The semiconductor materials of opposite polarity can form an electrical junction, e.g., a P-N junction, a P-N-P junction, an N-P-N junction, etc. The semiconductor material of a first polarity type can be contacted by a first contact, and a second polarity type can be contacted by a second contact where the second contact traverses through material of the first polarity type but is electrically isolated by a dielectric liner. In an embodiment, the semiconductor material of the second polarity type can be contacted by a third contact (instead of or in addition to the second contact), where the third contact is a backside contact.

The semiconductor materials of first polarity type or carrier type and the second polarity type or carrier type are electrically isolated from active device regions using dielectric liners. A sequence of polarity selection in the S/D canyon can follow a same sequence of polarity as other devices on a wafer, or can have a different sequence.

In an embodiment, a method of forming a semiconductor device includes blocking spacer deposition along a S/D canyon to cover both top and bottom nanosheet edges. Bottom and top epitaxial regions are formed sequentially. First contacts are formed to the top epitaxial regions, and second contacts are formed to the bottom epitaxial regions. The second contacts can pass through the top epitaxial regions, isolated from top epitaxial regions by a dielectric liner.

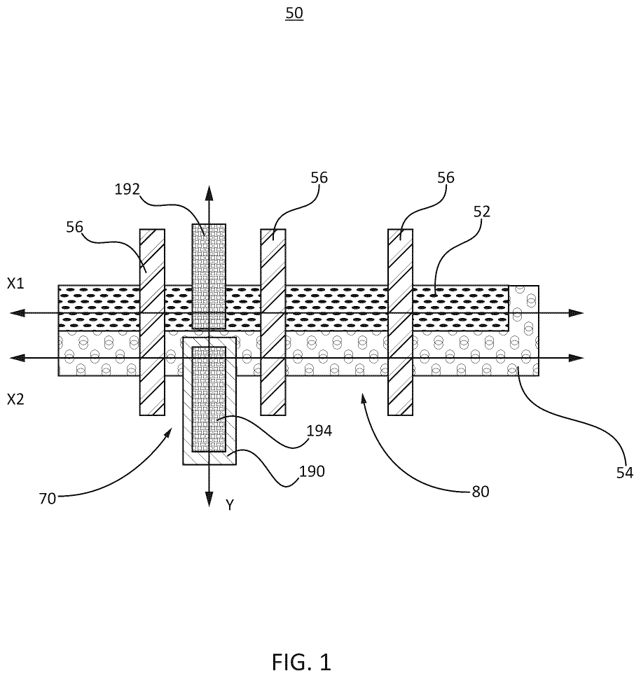

Referring now to the drawings in which like numerals represent the same or similar elements and initially to FIG. 1, a simplified layout view of a stacked FET device 50 is schematically shown. Corresponding X1 and X2 views are depicted throughout the FIGS. X1 and X2 views are in a passive device region 70 and depict processing of a P-N junction device, e.g., a diode. X1 (main device region) views are in an active device region 80 and depict processing a stacked FET devices. Active region lines 52 and 54 represent epitaxial regions (source/drain (S/D) regions) in the active device region 80 (main device region) and transistor channels under gate structures 56. Transistor channels are formed on the active region lines 52, 54 below the gate structures 56. Contacts 192 and 194 are also shown. Further description of the details of the structures will be described with reference to the following FIGS.

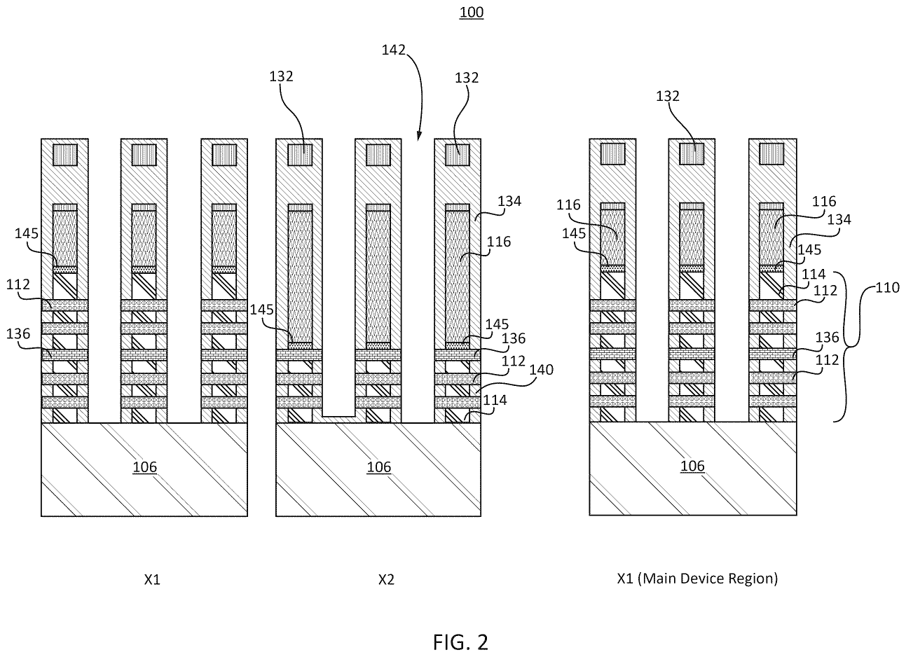

Referring to FIG. 2, devices and methods for manufacturing a nanosheet stacked field effect transistor (FET) device are shown in accordance with embodiments of the present invention. A wafer 100 includes a substrate 106 having multiple layers on which a semiconductor device will be fabricated. FIG. 2 depicts views X1, X2 and X1 (main device region) (or active device region 80) taken at corresponding sections in FIG. 1. X1 (main device region) shows a portion along section line X1 where an active portion of a junction device will be shown.

The substrate 106 can include any suitable substrate structure, e.g., a bulk semiconductor, a semiconductor-on-insulator (SOI) substrate, etc., and preferably includes a monocrystalline semiconductor. In one example, the substrate 106 can include a silicon-containing material. Illustrative examples of Si-containing materials suitable for the substrate 106 can include, but are not limited to, Si, SiGe, SiGeC, SiC and multi-layers thereof. Although silicon is the predominantly used semiconductor material in wafer fabrication, alternative semiconductor materials can be employed as additional layers, such as, but not limited to, germanium, gallium arsenide, gallium nitride, silicon germanium, cadmium telluride, zinc selenide, etc.

A layer stack or stacks are applied to or formed on the substrate 106. In an embodiment, one or more nanosheets 110 are applied to the substrate 106. The nanosheet 110 includes alternating semiconductor layers 112, and semiconductor layers 114 of different semiconductor materials. The alternating layers can be epitaxially grown using different chemistries to form layers having different properties. In an embodiment, the semiconductor layers 112 form transistor channels and can include Si although other semiconductor materials can be employed. The semiconductor layers 114 between the semiconductor layers 112 forming transistor channels can include SiGe.

The nanosheet 110, which includes the semiconductor layers 112, can be patterned. In an embodiment, a hard mask or cap 132 may be formed by blanket depositing a layer of hard mask material, providing a patterned photoresist on top of the layer of hard mask material, and then etching the layer of hard mask material to provide the hard mask pattern for etching the nanosheet 110. The patterned photoresist can be produced by applying a blanket photoresist layer to the surface of the hard mask material and exposing the photoresist layer to a pattern of radiation, and then developing the pattern into the photoresist layer utilizing resist developer. The pattern in the photoresist layer is transferred to the hard mask by an etch process.

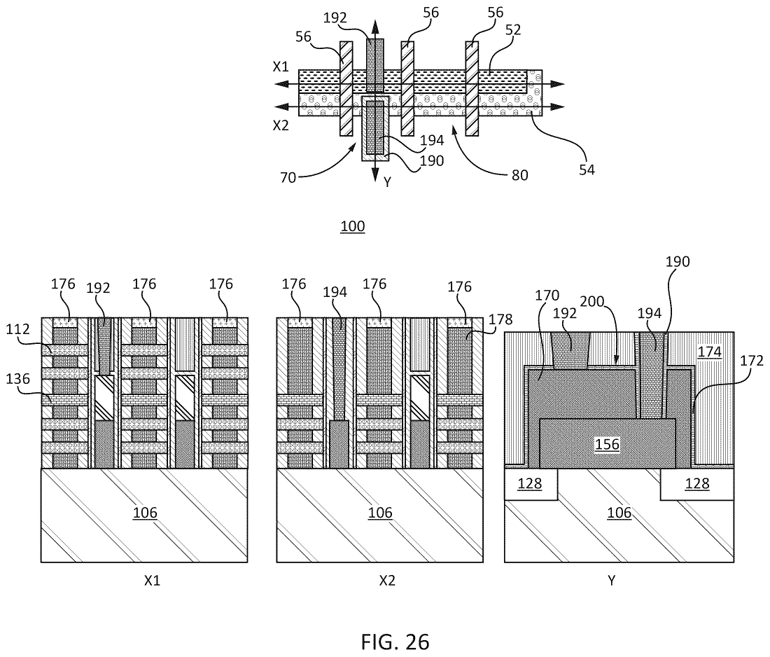

Openings formed through the nanosheet 110 can be etched, for example, by an anisotropic etch process, such as a reactive ion etch (RIE) or an ion beam etch (IBE). The etch process can be employed to further etch the substrate 106 to form shallow trenches therein in accordance with the openings. Shallow trench isolation (STI) regions or STI 128 (shown in FIG. 26) can be formed in these etched trenches. STI 128 can be formed by depositing dielectric material, such as, e.g., SiO₂, SiOₓN_{y}, SiCHO, SiCN, SiCNO or other suitable compounds. STI 128 can be deposited using chemical vapor deposition (CVD), although other deposition methods can be employed. The STI 128 can then be etched, e.g., by RIE, to a level of the substrate 106.

A filler material 116 is formed over the semiconductor material stacks. The filler material 116 can include a polysilicon, amorphous Si or other selectively removeable material. Spacers 134 can include a nitride, although other dielectric materials can be employed. Inner spacers 140 are formed and include a deposited dielectric material. In an embodiment, the inner spacers 140 are formed in place of laterally recessed layers (the semiconductor layers 114) of the nanosheet 110.

A middle dielectric isolation (MDI) 136, which can include an oxide, provides a demarcation point for vertical sectioning source/drain (S/D) canyons 142. An upper dielectric isolation layer 145, which can include an oxide, also provides a demarcation point for vertical sectioning on the MDI 136.

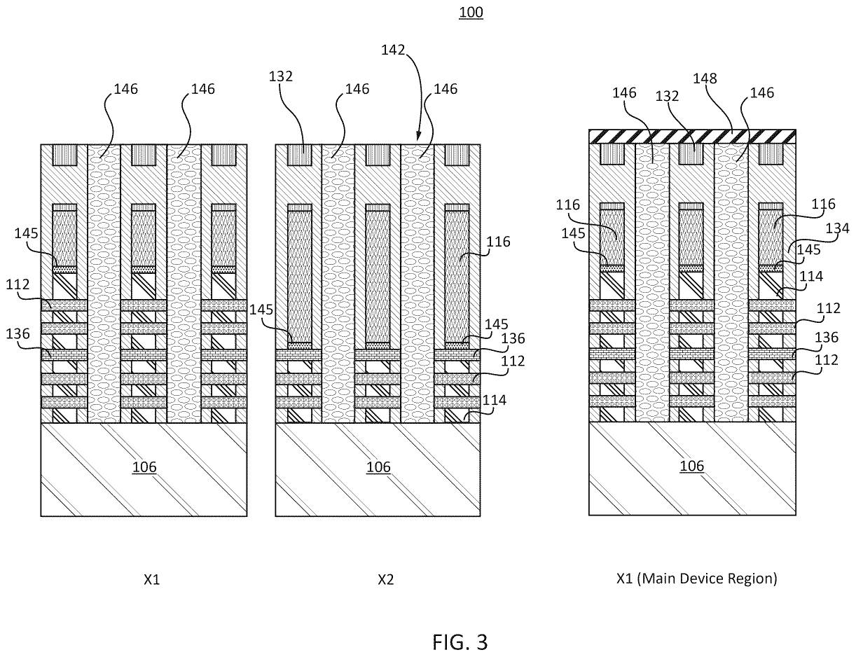

Referring to FIG. 3, a fill material 146 is deposited over the wafer 100 to fill in the S/D canyons 142. The fill material 146 can include a spin on glass (SOG) or other dielectric material. A planarization process, such as chemical mechanical polishing (CMP) can be employed to remove excess material from a top surface of the wafer 100. The CMP stops on the caps 132. A block mask 148 is deposited over the wafer 100 and patterned to block an active device region for section X1 (main device region) as opposed to a passive device region depicted by section X1.

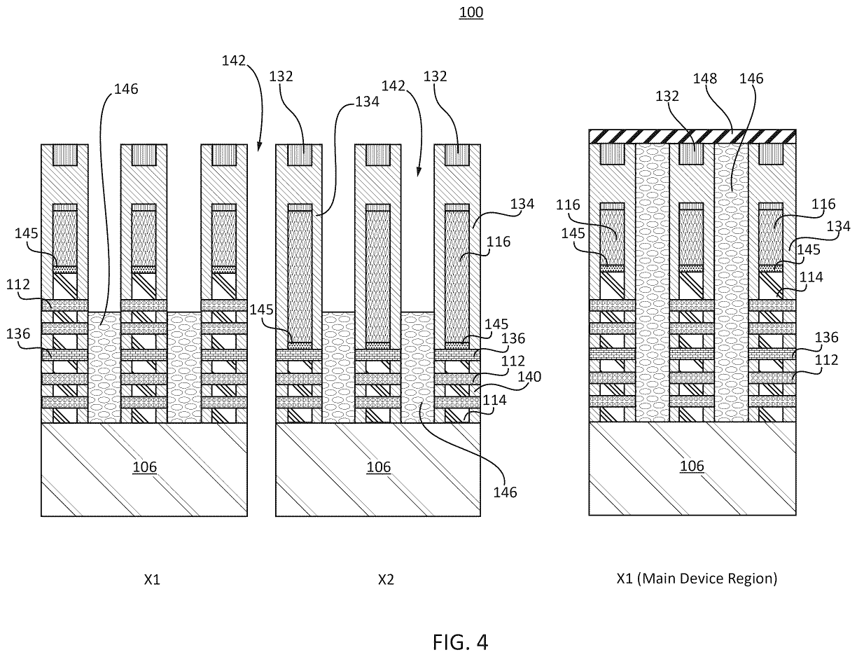

Referring to FIG. 4, the fill material 146 is partially recessed within the S/D canyons 142. The recess etch can include any suitable etching process. The etching process removes the fill material 146 in areas not blocked by the block mask 148.

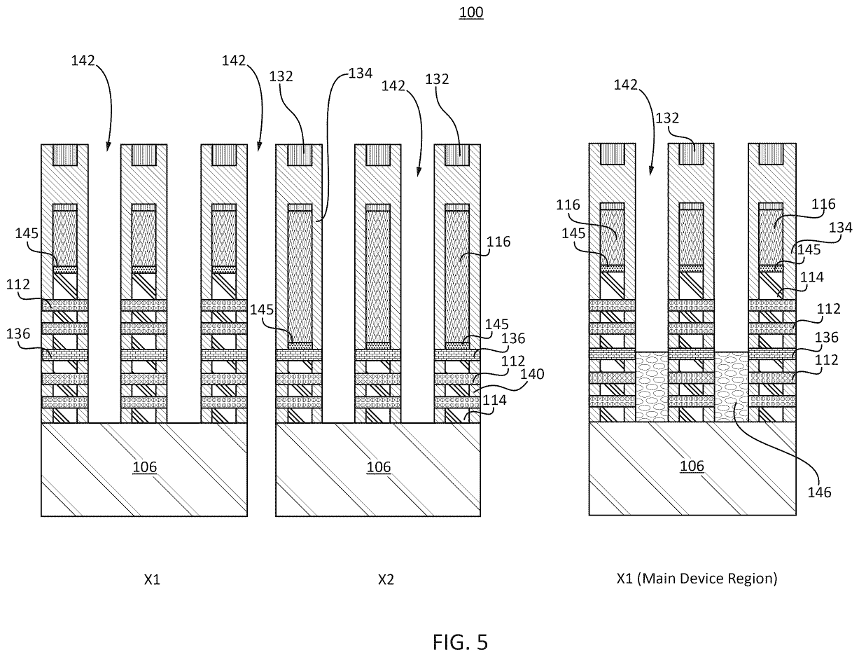

Referring to FIG. 5, the fill material 146 is recessed again after the removal of the block mask 148. The fill material is completely removed in the passive region of X1 and the X2 but remains in the active region of X1 (main device region) within the S/D canyons 142 to a position below the MDI 136. The recess etch can include any suitable etching process.

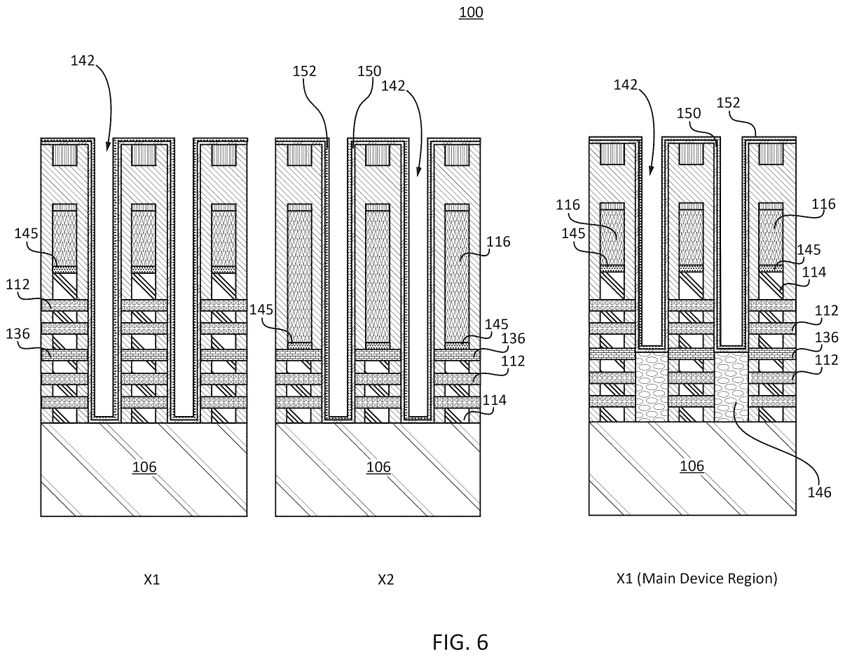

Referring to FIG. 6, blocking spacers 150 and 152 are deposited over the wafer 100 into the S/D canyons 142. The blocking spacer 150 and the blocking spacer 152 are selectively removable relative to one another. In addition, the blocking spacer 150 is selectively removable relative to the materials unto which it is formed. The blocking spacers 150, 152 can be deposited using a conformal deposition process, such as chemical vapor deposition (CVD), atomic layer deposition (ALD), or any other suitable deposition process.

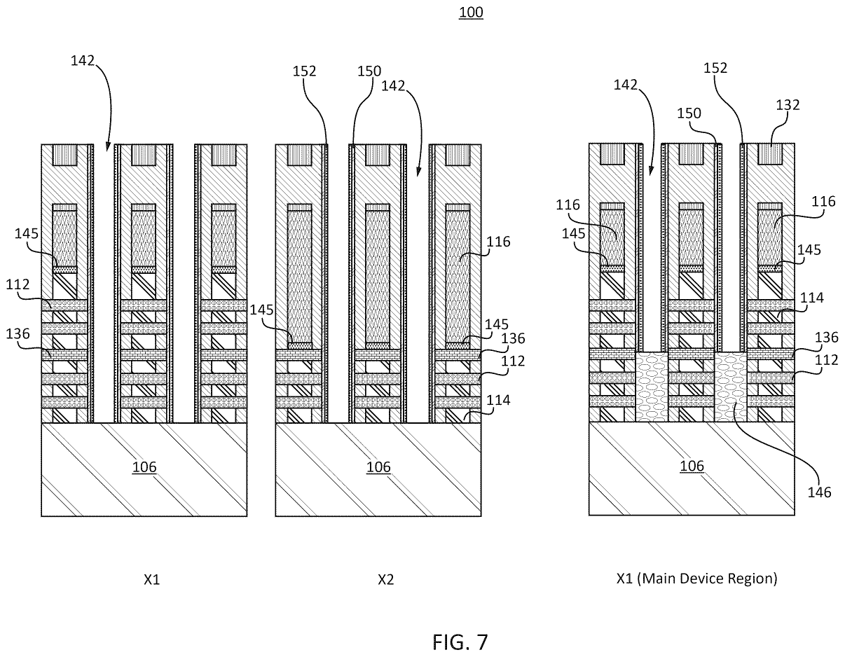

Referring to FIG. 7, a recess etch is performed to remove the blocking spacers 150, 152 from horizontal surfaces. The recess etch can include, e.g., RIE. The recess etch exposes the substrate 106 (in section X1 and X2) and the fill material 146 (X1 (main device region)). The remaining portions of the blocking spacers 150, 152 line the sidewalls of the S/D canyons 142.

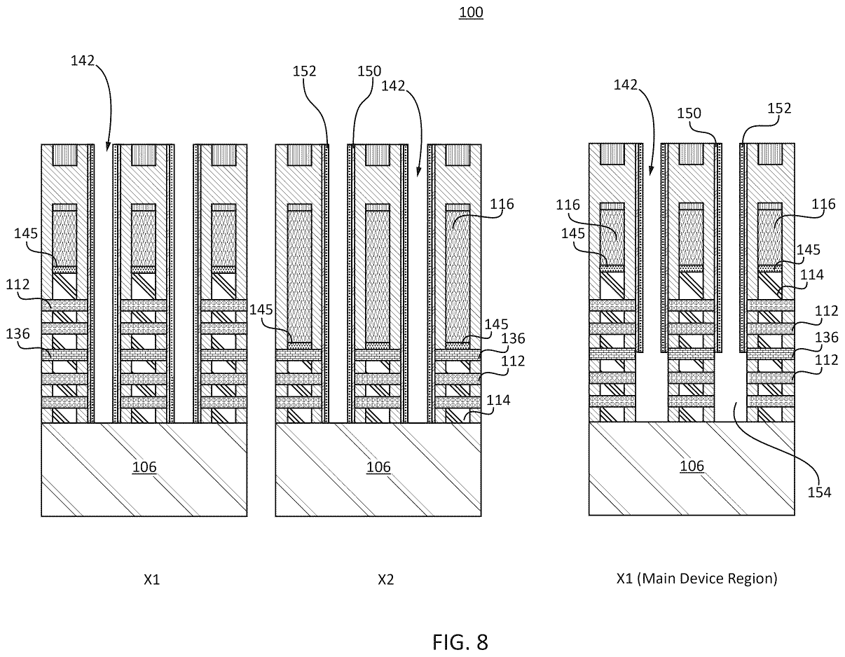

Referring to FIG. 8, the fill material 146 is removed from the main device region (X1 (main device region)). The fill material 146 is completely removed forming regions 154 and leaving the blocking spacers 150, 152 terminated at a position within the MDI 136 in the active region of X1 (main device region) within the S/D canyons 142. The fill material 146 can be etched by any suitable etching process.

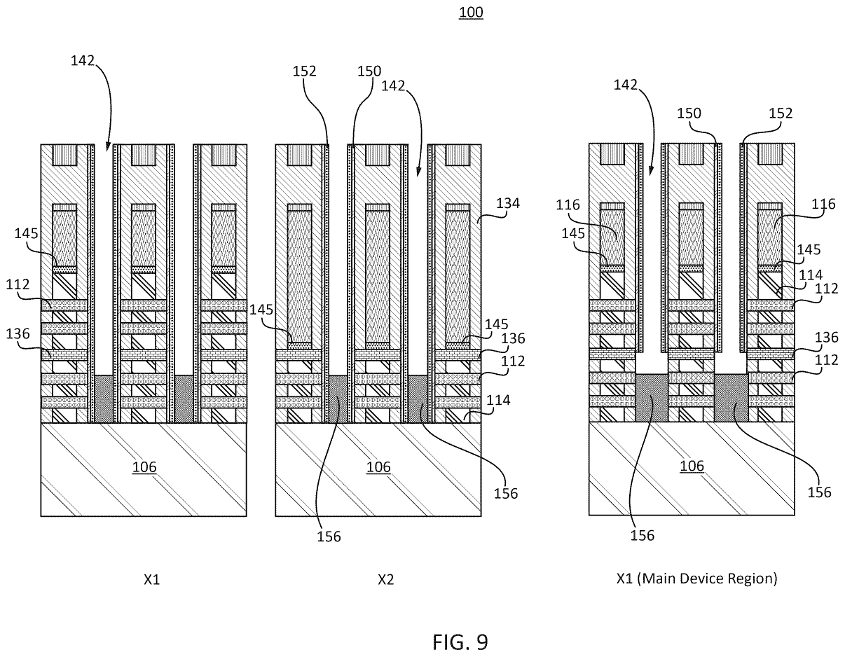

Referring to FIG. 9, an epitaxial growth process is performed to form bottom epitaxial regions 156. The bottom epitaxial regions 156 can include, e.g., Si or SiGe. In an embodiment, the bottom epitaxial regions 156 can include a polarity and can be designated as N-type or P-type regions. The P-type and N-type regions can have different materials selected for the bottom epitaxial regions 156. For example, if the bottom epitaxial regions 156 include N-type, then the bottom epitaxial regions 156 can include Si. In another example, if the bottom epitaxial regions 156 include P-type, then the bottom epitaxial regions 156 can include SiGe. The bottom epitaxial regions 156 can be appropriately doped during the formation of the bottom epitaxial regions 156 by epitaxial growth. For example, the bottom epitaxial regions 156 can be doped by introducing p dopants (e.g., B, Ga, etc.) during epitaxial formation. Similarly, the bottom epitaxial regions 156 can be doped by introducing n dopants (e.g., P, As, etc.) during epitaxial formation.

The bottom epitaxial regions 156 are grown to a height within the S/D canyons 142 that is below the MDI 136. The bottom epitaxial regions 156 are grown directly on the substrate 106 and therefore benefit from single crystal growth. The regions 154 are not completely filled by the bottom epitaxial regions 156.

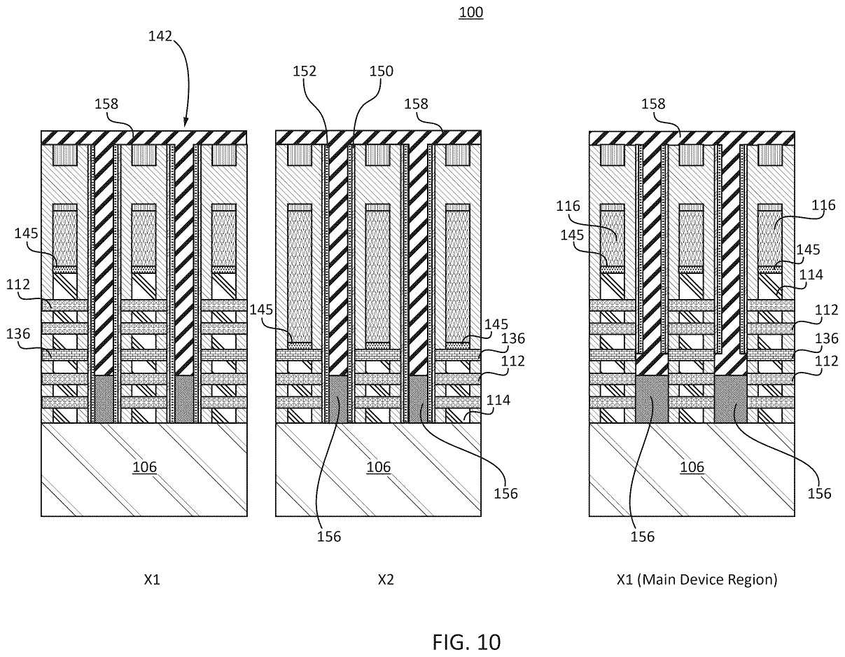

Referring to FIG. 10, another fill material 158 is deposited over the wafer 100 to fill the S/D canyons 142 over the blocking spacer 152 and the bottom epitaxial regions 156. In an embodiment, the fill materials 158 can include an optical planarizing layer (OPL), although other organic polymer materials can be employed to fill the S/D canyons 142.

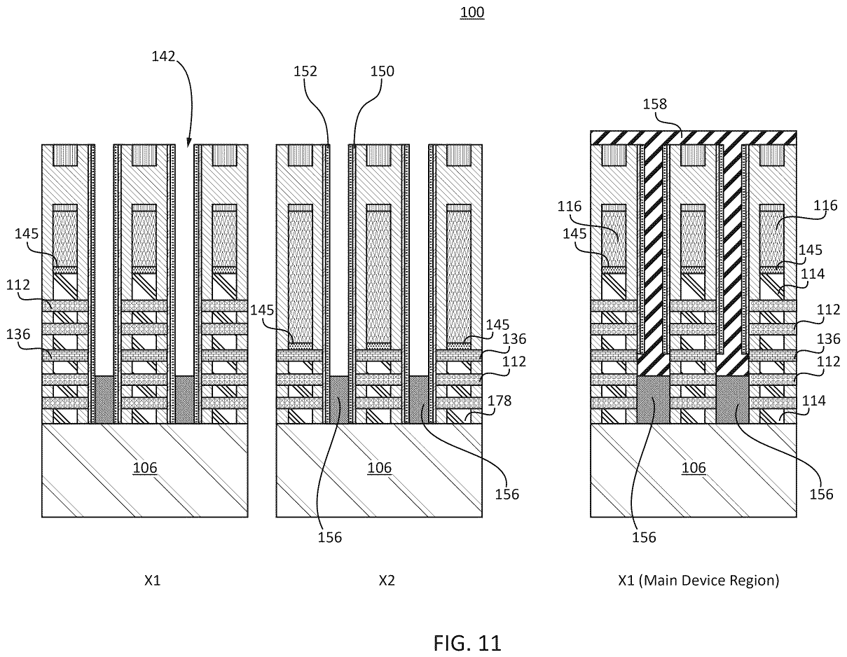

Referring to FIG. 11, a blocking mask (not shown) is formed and patterned over the main device region (X1 (main device region)) so that the fill material 158 can be removed from unblocked regions. The removal of the fill material 158 exposes the bottom epitaxial regions 156 in the unblocked regions.

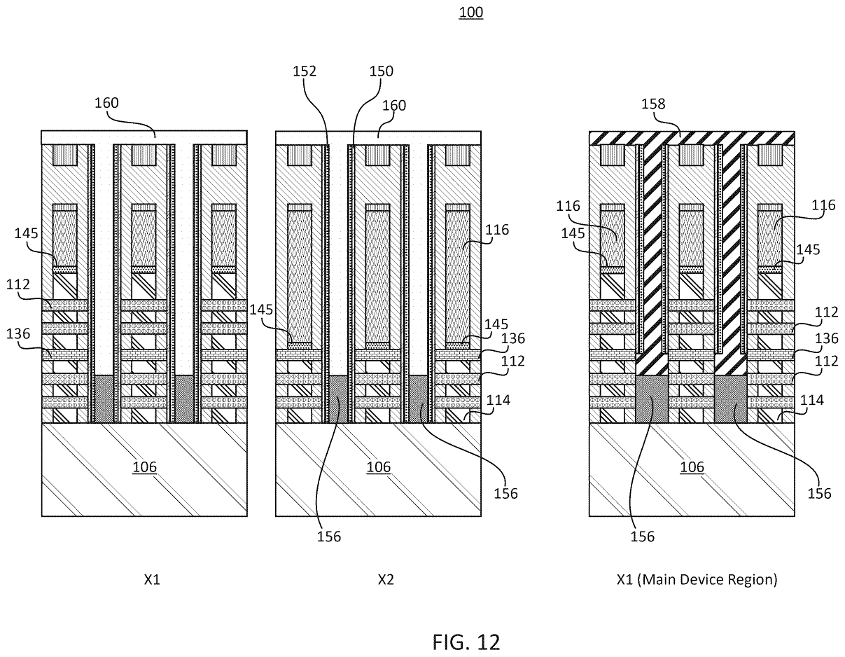

Referring to FIG. 12, fill material 160 is deposited over the wafer 100 to fill the S/D canyons 142 over the blocking spacer 152 and the bottom epitaxial regions 156. In an embodiment, the fill material 158 can include a spin on glass (SOG), although other materials can be employed to fill the S/D canyons 142.

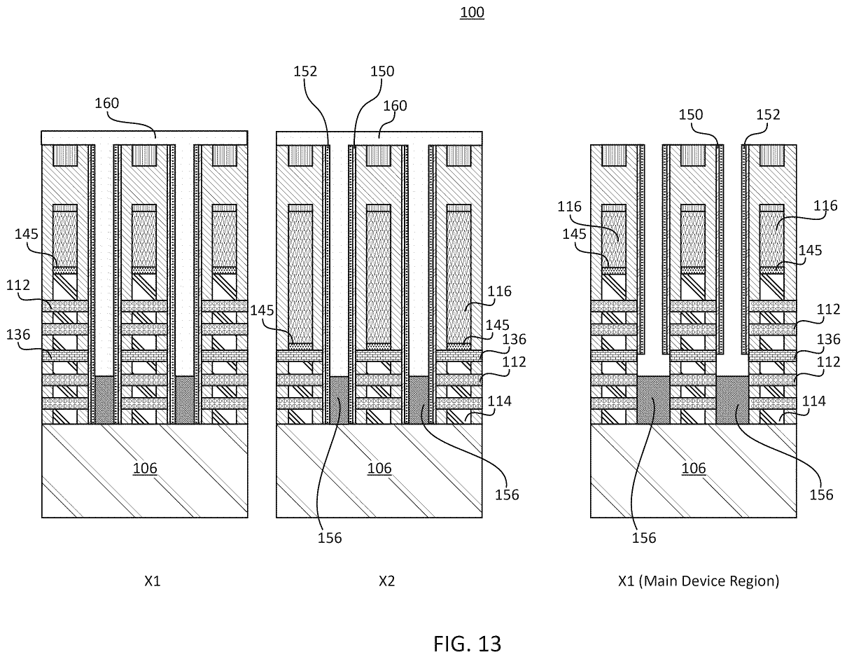

Referring to FIG. 13, the fill material 158 is removed to unblock the S/D canyons 142 in the main device region. If OPL is employed for the fill material 158 then an ashing process can be performed. Otherwise, an etch selective to the fill material 160 can be performed to remove the fill material 158.

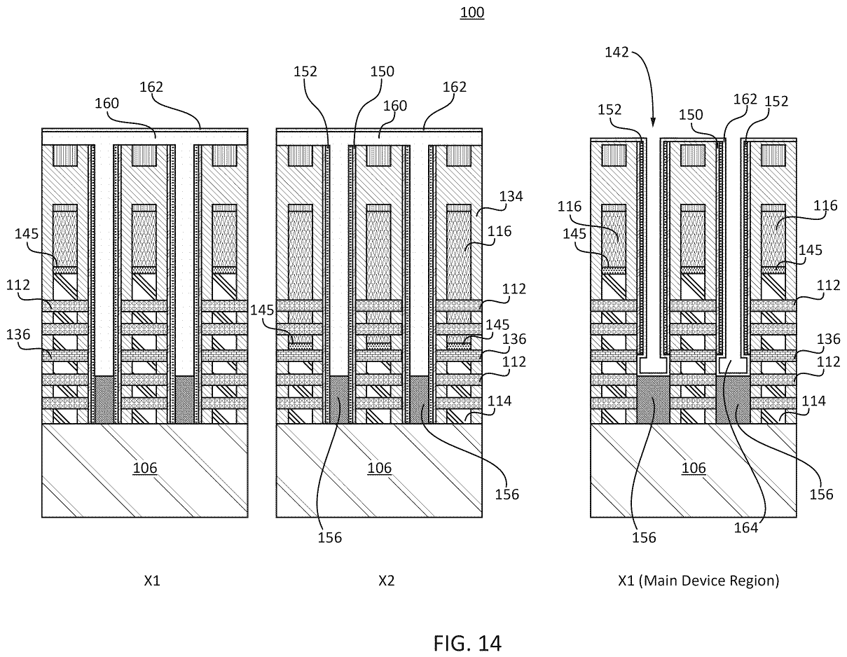

Referring to FIG. 14, a dielectric liner 162 is formed over the fill material 160. In the main device region, the dielectric liner 162 is formed over the blocking spacer 152, exposed sidewalls of the S/D canyons 142 and the bottom epitaxial regions 156. In an embodiment, the dielectric liner 162 can include a same material as the blocking spacer 152 which it contacts. The dielectric liner 162 can include, e.g., a nitride.

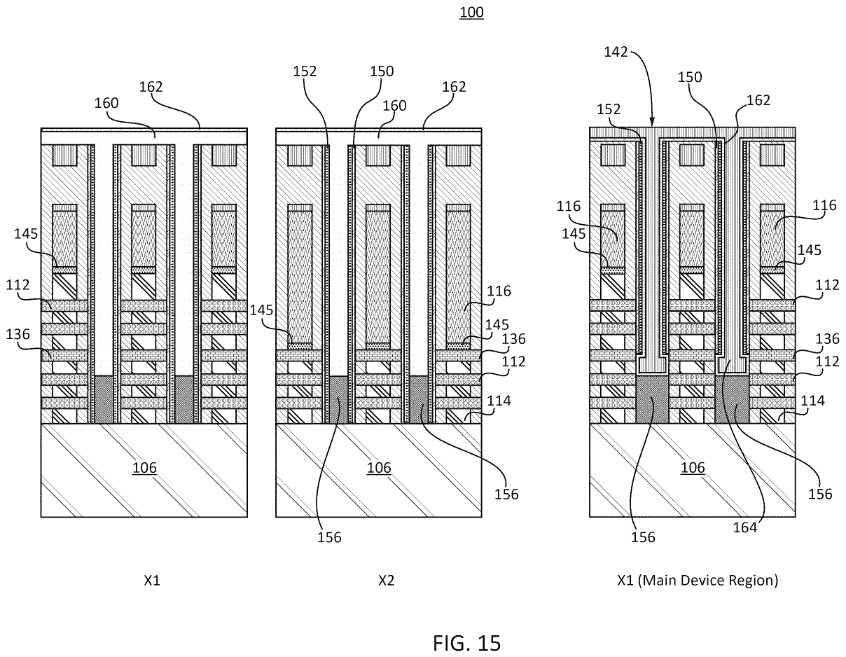

Referring to FIG. 15, the S/D canyons 142 in the main device region are filled with a dielectric material 164. Since there are spaces that need to be filled deep in the S/D canyons 142, a flowable material, such as a flowable CVD (FCVD) oxide can be employed. FCVD enhances gap-fill capabilities especially in high-aspect-ratio structures. FCVD includes a combination of deposition and cleaning radicals to create a uniform film especially in small node devices (e.g., sub-20 nm devices). The dielectric material 164 is then planarized, e.g., by CMP.

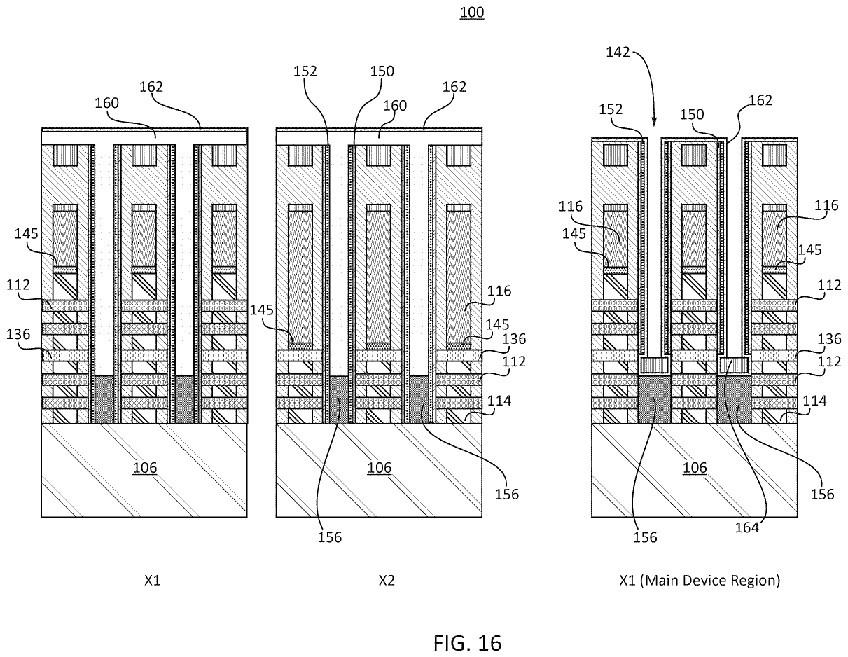

Referring to FIG. 16, a recess etch is performed to remove the dielectric material 164 from the S/D canyons 142 in the main device area. The recess etch can be timed to permit a level of the dielectric material 164 to be recessed to the MDI 136. At this position, the dielectric material 164 is slightly wider due to the earlier recess of the blocking spacer 150. The recess etch can include a wet or a dry etch that selectively removes the dielectric materials 164 with respect to the surrounding materials (e.g., dielectric liner 162).

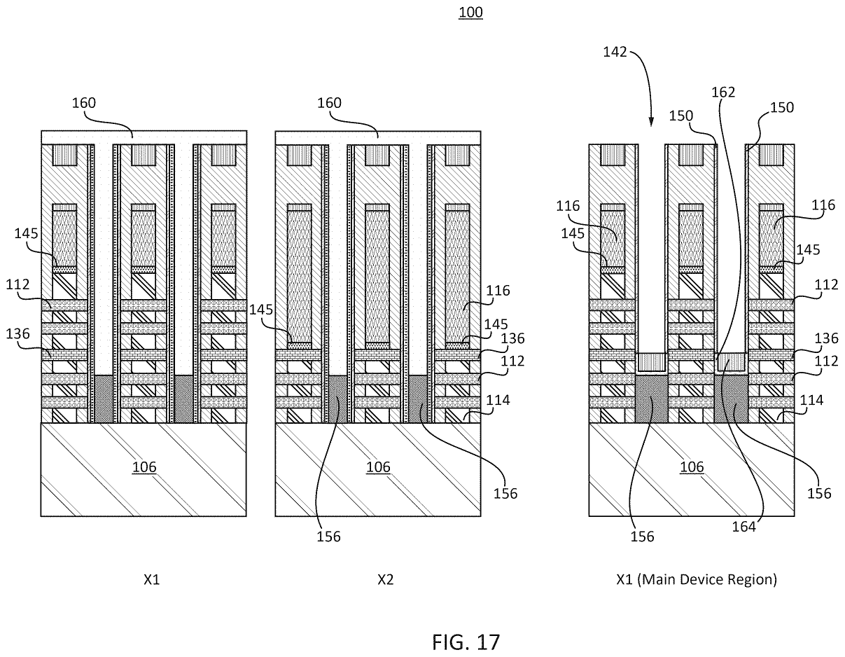

Referring to FIG. 17, the dielectric liner 162 is removed in exposed areas by a selective etch process, e.g., a dry or wet etch. The dielectric liner 162 remains in areas protected by the dielectric material 164 in the S/D canyons 142 in the main device region. The removal of the dielectric liner 162 exposes the blocking spacer 150 in the S/D canyons 142 in the main device region.

Referring to FIG. 18, the dielectric material 164 is removed by a selective etch process, e.g., a dry or wet etch. The dielectric material 164 is removed from the S/D canyons 142 in the main device region to expose the dielectric liner 162, which is formed over the bottom epitaxial regions 156. The removal of the dielectric material 164 exposes the blocking spacer 152 and the bottom epitaxial regions 156 in the S/D canyons 142 in the passive device region (e.g., sections X1 and X2).

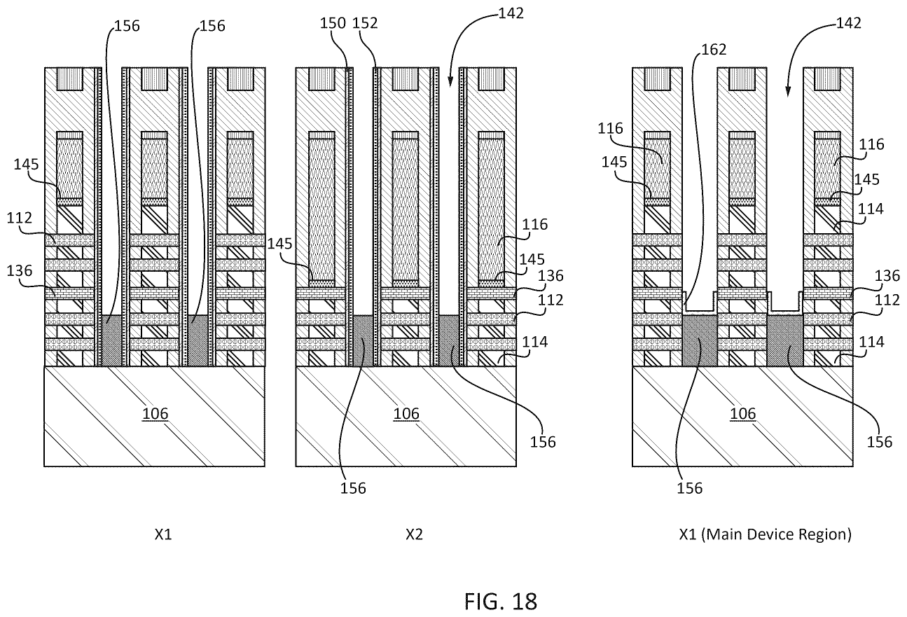

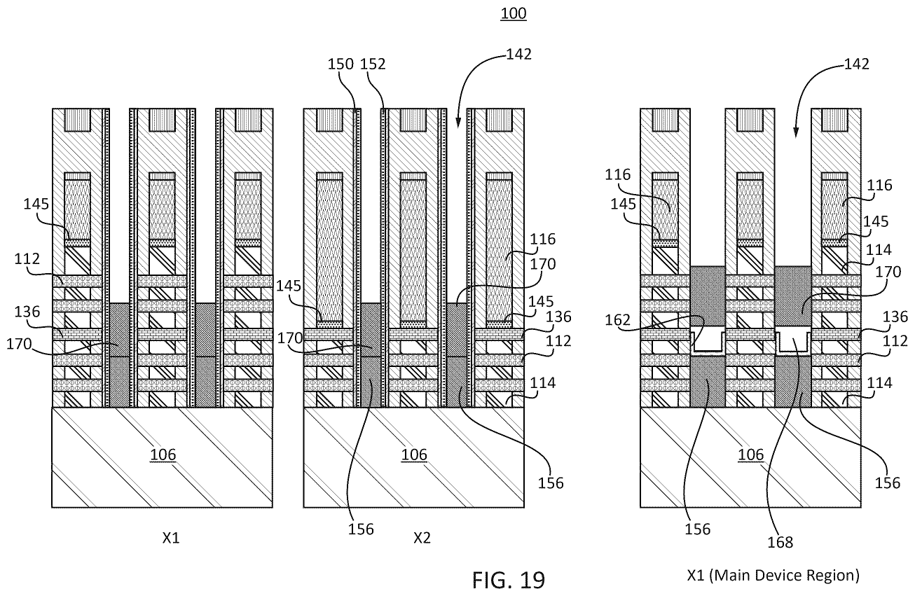

Referring to FIG. 19, an epitaxial growth process is performed to form top epitaxial regions 170. The top epitaxial regions 170 can include, e.g., Si or SiGe. In an embodiment, the top epitaxial regions 170 can include a polarity opposite that of the bottom epitaxial regions 156 and can be designated as N-type or P-type regions. The P-type and N-type regions can have different materials selected for the top epitaxial regions 170. For example, if the top epitaxial regions 170 include N-type, then the bottom epitaxial regions 156 can include Si. In another example, if the top epitaxial regions 170 include P-type, then the top epitaxial regions 170 can include SiGe. The top epitaxial regions 170 can be appropriately doped during the formation of the top epitaxial regions 170 by epitaxial growth. For example, the top epitaxial regions 170 can be doped by introducing p dopants (e.g., B, Ga, etc.) during epitaxial formation. Similarly, the top epitaxial regions 170 can be doped by introducing n dopants (e.g., P, As, etc.) during epitaxial formation.

The top epitaxial regions 170 are grown from a surface of the bottom epitaxial regions 156 in the passive device region since the semiconductor layers 112 are blocked off by the blocking spacers 150 and 152. The top epitaxial regions 170 are grown using only the semiconductor layers 112 in the main device region since the bottom epitaxial regions 156 are blocked off using remining portions of the dielectric liner 162. With the presence of the dielectric liner 162 and the MDI 136 in the S/D canyons 142 in the main device area, there is no epitaxial growth in the regions 168 where a gap is formed.

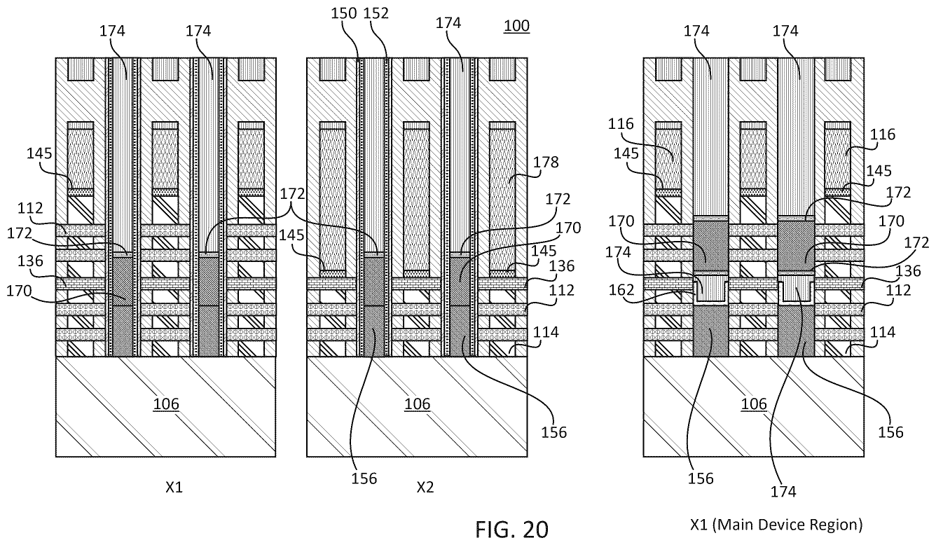

Referring to FIG. 20, a dielectric liner 172 is selectively deposited on exposed surfaces of the top epitaxial regions 170. In an embodiment, the dielectric liner 172 includes, e.g., a nitride. Another fill material 174 is deposited over the wafer 100 to fill the S/D canyons 142 over the blocking spacer 152, the top epitaxial regions 170 and the region 168 (FIG. 19). The fill material 174 can include, e.g., a flowable CVD oxide.

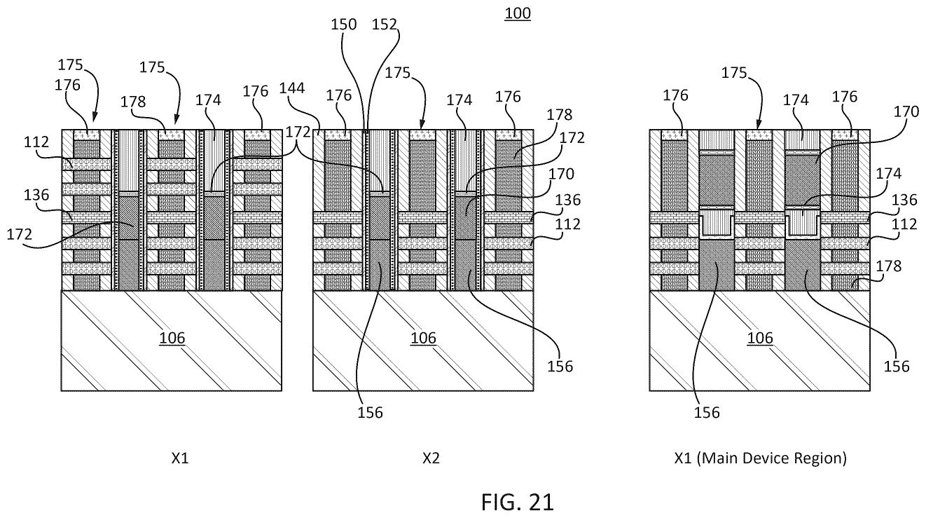

Referring to FIG. 21, materials above the upper dielectric isolation 144 are removed. A replacement metal gate (RMG) process is performed which removes and replaces the semiconductor layers 114 (e.g. SiGe) (or dummy gates if employed) with a gate conductor 178. A gate dielectric (not shown) is deposited to cover the semiconductor layers 112 (transistor channels) and fill spaces left by the semiconductor layers 114. The RMG process forms High-K Metal Gate (HKMG) structures for selectively activating FETs. The gate conductor 178 can include any conductive metal including, but not limited to W, Ni, Ti, Mo, Ta, Cu, Pt, Ag, Au, Ru, Ir, Rh, and Re, and alloys that include at least one of these conductive materials. The gate conductor 178 can include one or more layers of conductive materials. In one example, a second conductive material may be formed. When a combination of conductive elements is employed, an optional diffusion barrier material such as TaN or WN may be formed between the conductive materials. The gate conductor 178 can be deposited by CVD, PECVD, ALD or other suitable deposition process.

Self-aligned caps (SAC) 176 are formed in recesses formed above the gate conductors 178. The SACs 176 can include, e.g., a nitride. A planarization process (e.g., CMP) can be employed to planarize a free surface of the wafer 100. Gate structures 175 are constructed across the wafer 100 in the main device region and passive device regions. The S/D canyons 142 are disposed between the gate structures 175.

The bottom epitaxial regions 156 and the top epitaxial regions 170 form S/D regions for FET devices in the main device region (80 FIG. 1).

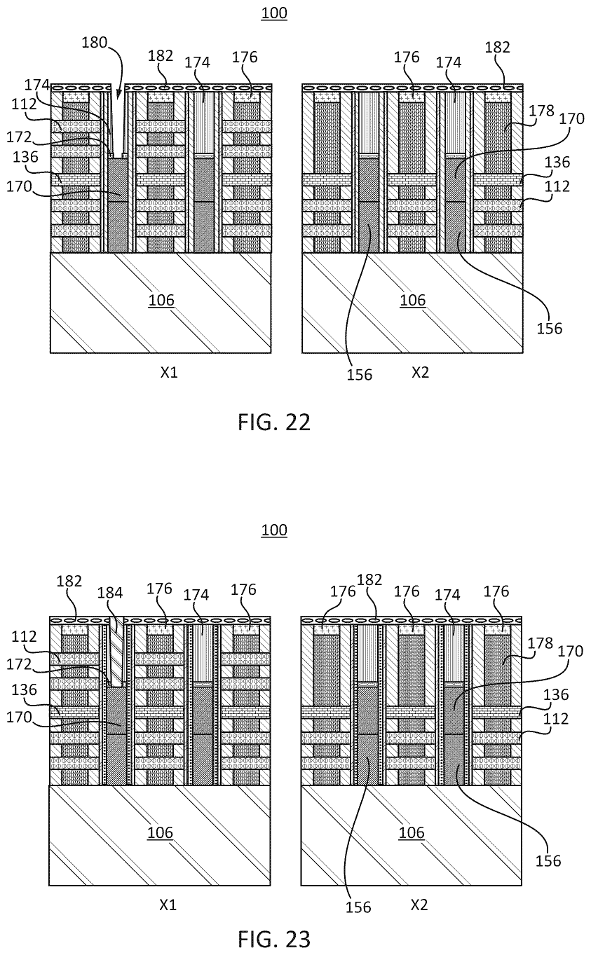

Referring to FIG. 22, a blocking mask 182, such as, e.g., a middle of the line (MOL) hard mask, is deposited over the wafer 100. The blocking mask 182 can include a material that permits selective etching of underlying materials, e.g., to form contact holes 180 in the fill material 174. The blocking mask 182 can be patterned using a lithographic process to provide openings corresponding to contact holes 180. An etch process, e.g., RIE, can be performed to etch the contact holes 180 into the fill material 174 and break through the dielectric liner 172 to expose the top epitaxial regions 170 (section X1). Since the main device area is not involved in the formation of the contacts in the next steps, the X1 (main device region) view is omitted.

Referring to FIG. 23, a contact plug 184 is formed in the contact hole 180 by depositing a fill dielectric over the wafer 100. The contact plug 184 can include, e.g., OPL, although any suitable material can be employed. A planarization process (e.g., CMP) can be employed to remove access material of the contact plug 184.

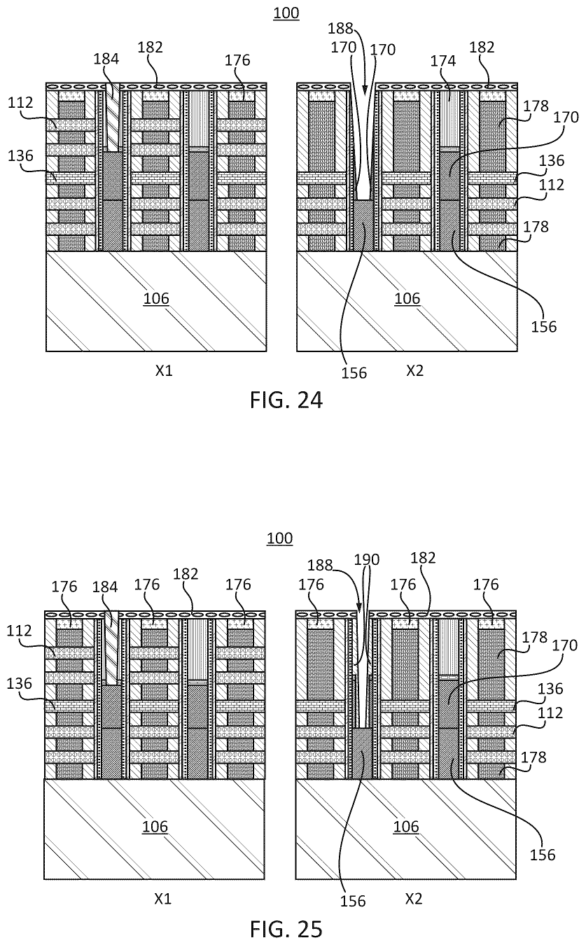

Referring to FIG. 24, the blocking mask 182 is again patterned to form contact holes 188 in the fill material 174. The blocking mask 182 can be patterned using a lithographic process to provide openings corresponding to contact holes 188. An etch process, e.g., RIE, can be performed to etch the contact holes 188 into the fill material 174 and break through the dielectric liner 172 to expose the top epitaxial regions 170 (section X2). The etching can continue to form an opening into and through the top epitaxial regions 170 to expose the bottom epitaxial regions 156. Since the main device area is not involved in the formation of the contacts in the next steps, the X1 (main device region) view is omitted.

Referring to FIG. 25, a liner 190 is formed over the wafer 100 on the blocking mask 182 and in the contact holes 188. The liner 190 can include, e.g., a nitride, although other dielectric material can be employed. An etch process, e.g., RIE is performed to remove the liner from horizontal surfaces to expose the bottom epitaxial regions 156 in the contact hole 188. Since the main device area is not involved in the formation of the contacts in the next steps, the X1 (main device region) view is omitted.

Referring to FIG. 26, the contact plug 184 is removed to expose the top epitaxial regions 170. In some embodiments, a silicide liner, such as Ti, Ni, NiPt is deposited first over the exposed top epitaxial regions 170 and the exposed bottom epitaxial regions 156, then a diffusion barrier can be formed over the epitaxial regions in the trenches prior to a conductive fill. The diffusion barrier can include, e.g., TiN, TaN, or similar materials.

A conductive fill is performed to fill the contact hole 180 and the contact hole 188 on top of the diffusion barrier, if present. The conductive fill can include materials, such as, e.g., Cu, Ru, Mo, Rh, W, Ir, and alloys or combinations of these and other conductive materials. In a particularly useful embodiment, the conductive fill includes Cu. The conductive fill can be formed using a deposition method, such as, e.g., CVD, PECVD, ALD or any other suitable deposition method. The conductive fill is planarized, e.g., by CMP, to form contacts 192 and 194.

A P-N junction is formed between the top epitaxial regions 170 and the bottom epitaxial regions 156 to form, e.g., a diode 200. The diode 200 includes a first polarity connection (contact 192) of a first diffusion region (top epitaxial regions 170) and a second polarity connection (contact 194) of a second diffusion region (bottom epitaxial regions 156). Note that contact 194 is routed through a top epitaxial region 170 and is separated from the top epitaxial region 170 by the liner 190. The P-N junction interface has the top epitaxial regions 170 extend over three sides of the bottom epitaxial regions 156.

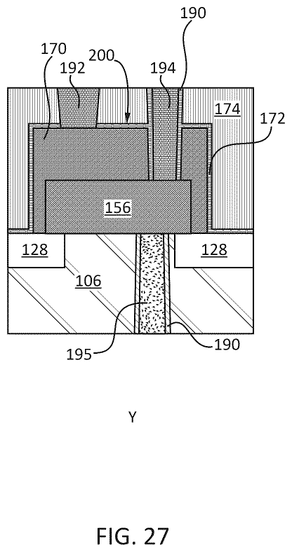

Referring to FIG. 27, in another embodiment, a P-N junction is formed between the top epitaxial region 170 and the bottom epitaxial region 156 to form, e.g., the diode 200. The diode 200 includes a first polarity connection (contact 192) of a first diffusion region (top epitaxial regions 170) and a second polarity connection (contact 195) of a second diffusion region (bottom epitaxial regions 156). Note that contact 195 is routed through the substrate 106, but can pass through any layers formed on a backside of the wafer 100 or device. In some embodiments, the substrate 106 is removed to form a backside power distribution network. In those embodiments, a device can include a backside interconnect layer that connects with the contact 195.

Note that fill material 174 can include an interlayer dielectric layer. An interlayer dielectric layer can include any suitable material, e.g., selected from the group consisting of silicon containing materials such as SiO₂, Si₃N₄, SiOₓN_{y}, SiC, SiCO, SiCOH, and SiCH compounds, the above-mentioned silicon containing materials with some or all of the Si replaced by Ge, carbon doped oxides, inorganic oxides, inorganic polymers, hybrid polymers, organic polymers such as polyamides or SiLK™, other carbon containing materials, organo-inorganic materials such as spin-on glasses and silsesquioxane-based materials, and diamond-like carbon (DLC), also known as amorphous hydrogenated carbon, α-C:H).

In accordance with embodiments of the present invention, devices and methods are described which include integrating a P-N diode within a stacked FET device (main device). The devices and methods include employing pristine crystalline material for the formation of the P-N junction of the diode. By blocking the sides of nanosheets using dielectric liners, single crystal epitaxial growth of semiconductor structure can be obtained in a S/D canyon using a single crystal substrate as a starting growth surface. Subsequent growth of semiconductor materials of different carrier types gives atomically pristine interfaces to provide excellent electrical junctions. By using dielectric liners in a contact trench passing through a top semiconductor structure, and/or by employing a backside contact, a bottom semiconductor structure can be contacted.

Exemplary applications/uses to which the present invention can be applied include, but are not limited to semiconductor devices. Semiconductor devices can include processors, memory devices, application specific integrated circuits (ASICs), logic circuits or devices, combinations of these and any other circuit device. In such devices, one or more semiconductor devices can be included in a central processing unit, a graphics processing unit, and/or a separate processor- or computing element-based controller (e.g., logic gates, etc.). The semiconductor devices can include one or more on-board memories (e.g., caches, dedicated memory arrays, read only memory, etc.). In some embodiments, the semiconductor devices can include one or more memories that can be on or off board or that can be dedicated for use by a hardware processor subsystem (e.g., ROM, RAM, basic input/output system (BIOS), etc.).

In some embodiments, the semiconductor devices can include and execute one or more software elements. The one or more software elements can include an operating system and/or one or more applications and/or specific code to achieve a specified result. In still other embodiments, the semiconductor devices can include dedicated, specialized circuitry that perform one or more electronic processing functions to achieve a specified result. Such circuitry can include one or more field programmable gate arrays (FPGAs), and/or programmable applications programmable logic arrays (PLAs).

It is to be understood that aspects of the present invention will be described in terms of a given illustrative architecture; however, other architectures, structures, substrate materials and process features and steps can be varied within the scope of aspects of the present invention.

It will also be understood that when an element such as a layer, region or substrate is referred to as being “on” or “over” another element, it can be directly on the other element or intervening elements can also be present. In contrast, when an element is referred to as being “directly on” or “directly over” another element, there are no intervening elements present. It will also be understood that when an element is referred to as being “connected” or “coupled” to another element, it can be directly connected or coupled to the other element or intervening elements can be present. In contrast, when an element is referred to as being “directly connected” or “directly coupled” to another element, there are no intervening elements present.

The present embodiments can include a design for an integrated circuit chip, which can be created in a graphical computer programming language, and stored in a computer storage medium (such as a disk, tape, physical hard drive, or virtual hard drive such as in a storage access network). If the designer does not fabricate chips or the photolithographic masks used to fabricate chips, the designer can transmit the resulting design by physical means (e.g., by providing a copy of the storage medium storing the design) or electronically (e.g., through the Internet) to such entities, directly or indirectly. The stored design is then converted into the appropriate format (e.g., GDSII) for the fabrication of photolithographic masks, which typically include multiple copies of the chip design in question that are to be formed on a wafer. The photolithographic masks are utilized to define areas of the wafer (and/or the layers thereon) to be etched or otherwise processed.

Methods as described herein can be used in the fabrication of integrated circuit chips. The resulting integrated circuit chips can be distributed by the fabricator in raw wafer form (that is, as a single wafer that has multiple unpackaged chips), as a bare die, or in a packaged form. In the latter case, the chip is mounted in a single chip package (such as a plastic carrier, with leads that are affixed to a motherboard or other higher level carrier) or in a multichip package (such as a ceramic carrier that has either or both surface interconnections or buried interconnections). In any case, the chip is then integrated with other chips, discrete circuit elements, and/or other signal processing devices as part of either (a) an intermediate product, such as a motherboard, or (b) an end product. The end product can be any product that includes integrated circuit chips, ranging from toys and other low-end applications to advanced computer products having a display, a keyboard or other input device, and a central processor.

It should also be understood that material compounds will be described in terms of listed elements, e.g., SiGe. These compounds include different proportions of the elements within the compound, e.g., SiGe includes SiₓGe₁₋ₓ where x is less than or equal to 1, etc. In addition, other elements can be included in the compound and still function in accordance with the present principles. The compounds with additional elements will be referred to herein as alloys.

Reference in the specification to “one embodiment” or “an embodiment”, as well as other variations thereof, means that a particular feature, structure, characteristic, and so forth described in connection with the embodiment is included in at least one embodiment. Thus, the appearances of the phrase “in one embodiment” or “in an embodiment”, as well any other variations, appearing in various places throughout the specification are not necessarily all referring to the same embodiment.

It is to be appreciated that the use of any of the following “/”, “and/or”, and “at least one of”, for example, in the cases of “A/B”, “A and/or B” and “at least one of A and B”, is intended to encompass the selection of the first listed option (A) only, or the selection of the second listed option (B) only, or the selection of both options (A and B). As a further example, in the cases of “A, B, and/or C” and “at least one of A, B, and C”, such phrasing is intended to encompass the selection of the first listed option (A) only, or the selection of the second listed option (B) only, or the selection of the third listed option (C) only, or the selection of the first and the second listed options (A and B) only, or the selection of the first and third listed options (A and C) only, or the selection of the second and third listed options (B and C) only, or the selection of all three options (A and B and C). This can be extended, as readily apparent by one of ordinary skill in this and related arts, for as many items listed.

The terminology used herein is for the purpose of describing particular embodiments only and is not intended to be limiting of example embodiments. As used herein, the singular forms “a,” “an” and “the” are intended to include the plural forms as well, unless the context clearly indicates otherwise. It will be further understood that the terms “comprises,” “comprising,” “includes” and/or “including,” when used herein, specify the presence of stated features, integers, steps, operations, elements and/or components, but do not preclude the presence or addition of one or more other features, integers, steps, operations, elements, components and/or groups thereof.

Spatially relative terms, such as “beneath,” “below,” “lower,” “above,” “upper,” “top,” “bottom” and the like, can be used herein for ease of description to describe one element's or feature's relationship to another element(s) or feature(s) as illustrated in the FIGS. It will be understood that the spatially relative terms are intended to encompass different orientations of the device in use or operation in addition to the orientation depicted in the FIGS. For example, if the device in the FIGS. is turned over, elements described as “below” or “beneath” other elements or features would then be oriented “above” the other elements or features. Thus, the term “below” can encompass both an orientation of above and below. The device can be otherwise oriented (rotated 90 degrees or at other orientations), and the spatially relative descriptors used herein can be interpreted accordingly. In addition, it will also be understood that when a layer is referred to as being “between” two layers, it can be the only layer between the two layers, or one or more intervening layers can also be present.

It will be understood that, although the terms first, second, etc. can be used herein to describe various elements, these elements should not be limited by these terms. These terms are only used to distinguish one element from another element. Thus, a first element discussed below could be termed a second element without departing from the scope of the present concept.

Having described preferred embodiments of devices and methods (which are intended to be illustrative and not limiting), it is noted that modifications and variations can be made by persons skilled in the art in light of the above teachings. It is therefore to be understood that changes may be made in the particular embodiments disclosed which are within the scope of the invention as outlined by the appended claims. Having thus described aspects of the invention, with the details and particularity required by the patent laws, what is claimed and desired protected by Letters Patent is set forth in the appended claims.

1. A semiconductor device, comprising:
gate structures having source/drain canyons disposed between the gate structures; and
a P-N junction integrated within the source/drain canyons, the P-N junction including:
a first epitaxial region of a first carrier type; and
a second epitaxial region of a second carrier type different from the first carrier type, the second epitaxial region vertically stacked on and in contact with the first epitaxial region.

2. The semiconductor device of claim 1, further comprising a first contact electrically coupled to the first epitaxial region.

3. The semiconductor device of claim 2, further comprising a second contact electrically coupled to the second epitaxial region.

4. The semiconductor device of claim 3, wherein the first contact and the second contact are routed on a same side of the P-N junction.

5. The semiconductor device of claim 3, wherein the first contact and the second contact are routed on opposite sides of the P-N junction.

6. The semiconductor device of claim 3, wherein the first contact extends through a second epitaxial region.

7. The semiconductor device of claim 6, further comprising:
a dielectric liner surrounding the second contact.

8. The semiconductor device of claim 1, wherein the first epitaxial region is in direct contact with a substrate.

9. The semiconductor device of claim 1, further comprising:
a backside contact electrically coupled to the first epitaxial region.

10. A semiconductor device, comprising:
gate structures having source/drain canyons disposed therebetween;
a P-N junction integrated within the source/drain canyons, the P-N junction forming a diode and including:
a first epitaxial region of a first carrier type; and
a second epitaxial region of a second carrier type different from the first carrier type, the second epitaxial region vertically stacked on and in contact with the first epitaxial region;
a first contact electrically coupled to the first epitaxial region; and
a second contact electrically coupled to the second epitaxial region.

11. The semiconductor device of claim 10, wherein the first contact and the second contact are routed on a same side of the P-N junction.

12. The semiconductor device of claim 10, wherein the first contact and the second contact are routed on opposite sides of the P-N junction.

13. The semiconductor device of claim 10, wherein the first contact extends through a second epitaxial region.

14. The semiconductor device of claim 10, further comprising:
a dielectric liner surrounding the second contact.

15. The semiconductor device of claim 10, wherein the first epitaxial region is in direct contact with a substrate.

16. The semiconductor device of claim 10, wherein the second contact is electrically coupled to the second epitaxial region from a frontside and further comprising a backside contact electrically coupled to the first epitaxial region.

17. A semiconductor device, comprising:
gate structures having source/drain canyons disposed therebetween;
a passive device region including a P-N junction integrated within the source/drain canyons, the P-N junction forming a diode and including:
a first epitaxial region of a first carrier type; and
a second epitaxial region of a second carrier type different from the first carrier type, the second epitaxial region vertically stacked on and in contact with the first epitaxial region, the second epitaxial region covering sides of the first epitaxial region;
a first contact electrically coupled to the first epitaxial region;
a second contact electrically coupled to the second epitaxial region; and
an active device region including stacked field effect transistors.

18. The semiconductor device of claim 17, wherein the first contact and the second contact are routed on a same side of the P-N junction.

19. The semiconductor device of claim 17, wherein the first contact and the second contact are routed on opposite sides of the P-N junction.

20. The semiconductor device of claim 17, wherein the first contact extends through a second epitaxial region and further comprises a dielectric liner surrounding the first contact.
